(19) United States
(12) Patent Application Publication
(10) Pub. No.: US 2018/0358040 A1
(43) Pub. Date: Dec. 13, 2018

(54) SUSPENSION BOARD WITH CIRCUITS

(71) Applicant: NITTO DENKO CORPORATION, Osaka (JP)

(72) Inventor: Yoshito FUJIMURA, Osaka (JP)

(73) Assignee: NITTO DENKO CORPORATION, Osaka (JP)

(21) Appl. No.: 15/996,875

(22) Filed: Jun. 4, 2018

(30) Foreign Application Priority Data
Jun. 9, 2017 (JP) 2017-114242

(51) Int. Cl. G11B 5/48; H05K 1/18; H05K 1/11; H05K 3/40; H05K 3/46; H05K 3/34; H05K 3/00

(52) U.S. Cl. CPC G11B 5/4826; H05K 1/181; H05K 1/115; H05K 3/4038; H05K 3/4644; H05K 2201/10121; H05K 3/0011; H05K 3/4007; H05K 2201/09027; H05K 2201/10159; H05K 2201/10083; H05K 3/341

(57) ABSTRACT

On the suspension board with circuits, a slider can be mounted, and a pedestal that supports the slider is included. The pedestal includes a first insulating layer, a first metal layer disposed on the first insulating layer, a second insulating layer disposed on the first metal layer, and a second metal layer disposed on the second insulating layer, and a third insulating layer disposed on the second metal layer. At least one of the first metal layer and second metal layer includes a plurality of wires arranged in parallel in spaced apart relation from each other.

### CROSS REFERENCE TO RELATED APPLICATION

The present application claims priority from Japanese Patent Application No. 2017-114242 filed on Jun. 9, 2017, the contents of which are hereby incorporated by reference into this application.

### BACKGROUND OF THE INVENTION

### Field of the Invention

The present invention relates to a suspension board with circuits, particularly to a suspension board with circuits used for a hard disk drive.

### Description of Related Art

Conventionally, for a suspension board with circuits, a suspension board with circuits having a slider with a magnetic head at a front end portion and mounted in a hard disk drive has been known.

In the suspension board with circuits, for increasing memory of a disk, mounting an electronic component such as a thermally assisted device including a laser diode have been proposed (for example, Japanese Unexamined Patent Publication No. 2013-246860).

Japanese Unexamined Patent Publication No. 2013-246860 discloses a suspension board including a mounting region for a magnetic head slider having a support that supports an end of the magnetic head slider. The support for the suspension board described in Japanese Unexamined Patent Publication No. 2013-246860 is formed on the metal substrate, and has a first metal layer provided so as to contact the metal substrate, and a support insulating layer that is provided on the first metal layer and supports the magnetic headslider.

The suspension board of Japanese Unexamined Patent Publication No. 2013-246860 allows stable mounting of the magnetic headslider and prevents damages to the magnetic head slider.

### SUMMARY OF THE INVENTION

Meanwhile, to precisely adjust the position and angle of the magnetic head, in addition to the heat-assisted device, for example, there has been proposed, for example, providing microactuators such as a pair of piezoelectric elements.

In such a suspension board in which such microactuators are mounted, the microactuator is disposed from the lower side, and therefore the metal substrate cannot be disposed in the region for mounting the microactuator.

Furthermore, to mount electronic components such as heat-assisted devices and microactuators, a region for forming wires have to be increased in the suspension board.

Meanwhile, in the suspension board of Japanese Unexamined Patent Publication No. 2013-246860, the support is provided on the metal substrate, and therefore to dispose the support, a dedicated space is necessary in a region where the metal substrate is present and wires are not formed. Therefore, disadvantages such as the following are caused: disposition of the support is largely limited, or wire design has to be considered for the disposition of the support.

The present invention provides a suspension board with circuits in which a dedicated space for disposing pedestals does not have to be provided.

The present invention [1] includes a suspension board with circuits, wherein a slider can be mounted thereon, the suspension board with circuits including: a pedestal that supports the slider, the pedestal includes a first insulating layer, a first metal layer disposed on the first insulating layer, a second insulating layer disposed on the first metal layer, a second metal layer disposed on the second insulating layer, and a third insulating layer disposed on the second metal layer, and at least one of the first metal layer and the second metal layer includes a plurality of wires arranged in parallel in spaced apart relation from each other.

With the suspension board with circuits, the pedestal includes the first insulating layer, first metal layer, second insulating layer, second metal layer, and third insulating layer, and at least one of the first metal layer and second metal layer include a plurality of wires. Thus, the pedestal can be provided in the region where the wires are formed, and therefore the dedicated space for disposing the pedestal does not have to be provided. As a result, degree of freedom improves regarding where the pedestals or wires are to be disposed.

The present invention [2] includes the suspension board with circuits of [1], wherein one of the first metal layer and the second metal layer includes the plurality of wires, and the other of the first metal layer and the second metal layer has a sheet shape extending in a plane direction of the suspension board with circuits so as to include at least two adjacent wires of the plurality of wires when projected in thickness direction.

With the suspension board with circuits, the other of the first metal layer and the second metal layer has a sheet shape across the two adjacent wires. Therefore, the pedestal has excellent rigidity, and even in the region where the metal supporting board is not included (for example, piezoelectric element mounting region to be described later), the slider can be supported reliably.

The present invention [3] includes the suspension board with circuits of [2], wherein the first metal layer includes the plurality of wires, and the second metal layer has the sheet shape.

With the suspension board with circuits, the second metal layer has a sheet shape across the two adjacent wires. Therefore, the pedestal has excellent rigidity, and even in the region where the metal supporting board is not included, the slider can be supported reliably.

The present invention [4] includes the suspension board with circuits of [2], wherein the first metal layer has the sheet shape, and the second metal layer includes the plurality of wires.

With the suspension board with circuits, the first metal layer has a sheet shape across the two adjacent wires. Therefore, the pedestal has excellent rigidity, and even in the region where the metal support layer is not included, the slider can be supported reliably.

The present invention [5] includes the suspension board with circuits of any one of [1] to [4], wherein a piezoelectric element can be mounted on the suspension board with circuits, the pedestal includes a first pedestal and a second pedestal, the first pedestal is disposed in a region where a slider mounting region overlaps a piezoelectric element mounting region, and does not include a metal support layer below the first insulating layer, the second pedestal is disposed in the slider mounting region, and includes a metal support layer below the first insulating layer.

With the suspension board with circuits, the first pedestal is positioned in the slider mounting region and piezoelectric element mounting region (slider and piezoelectric element mounting region), and the slider can be supported in the piezoelectric element mounting region. Therefore, the piezoelectric element mounting region can be effectively used. The second pedestal includes the metal support layer below the first insulating layer, and therefore the slider can be supported even more reliably.

With the suspension board with circuits of the present invention, the dedicated space the disposing the pedestal does not have to be provided, and therefore degree of freedom improves regarding where the pedestals or wires are to be disposed.

### BRIEF DESCRIPTION OF THE DRAWINGS

FIG. 1 shows a plan view of a first embodiment of the suspension board with circuits of the present invention (intermediate insulating layer, second conductive pattern, and insulating cover layer are omitted).

FIG. 2 shows a plan view of the suspension board with circuits shown in FIG. 1 (metal supporting board and first conductive pattern are omitted).

FIG. 3 shows a plan view of the suspension board with circuits shown in FIG. 1 (insulating base layer, intermediate insulating layer, and insulating cover layer are omitted).

FIG. 4 shows a cross sectional view along the line A-A of the suspension board with circuits shown in FIG. 1.

FIG. 5 shows a cross sectional view along the line B-B of the suspension board with circuits shown in FIG. 1.

FIG. 6 shows a cross sectional view along the line C-C of the suspension board with circuits shown in FIG. 1.

FIG. 7A to FIG. 7E are process diagrams for describing a method for producing the suspension board with circuits shown in FIG. 1.

FIG. 7A illustrating a step of preparing a metal supporting board, FIG. 7B illustrating a step of forming an insulating base layer, FIG. 7C illustrating a step of forming a first conductive pattern, FIG. 7D illustrating a step of forming an intermediate insulating layer, and FIG. 7E illustrating a step of forming a second conductive pattern.

Following FIG. 7E, FIG. 8F to FIG. 8I are process diagrams for describing the method for producing the suspension board with circuits shown in FIG. 1, FIG. 8F illustrating a step of forming an insulating cover layer, FIG. 8G illustrating a step of working a metal supporting board, FIG. 8H illustrating a step of mounting a slider unit, and FIG. 8I illustrating a step of mounting a piezoelectric element.

FIG. 9 shows a plan view of a second embodiment of the suspension board with circuits of the present invention (base insulating layer, intermediate insulating layer, and insulating cover layer are omitted).

FIG. 10 shows a cross sectional view taken along line A-A of the suspension board with circuits shown in FIG. 9.

FIG. 11 shows a cross sectional view taken along line B-B of the suspension board with circuits shown in FIG. 9.

### DETAILED DESCRIPTION OF THE INVENTION

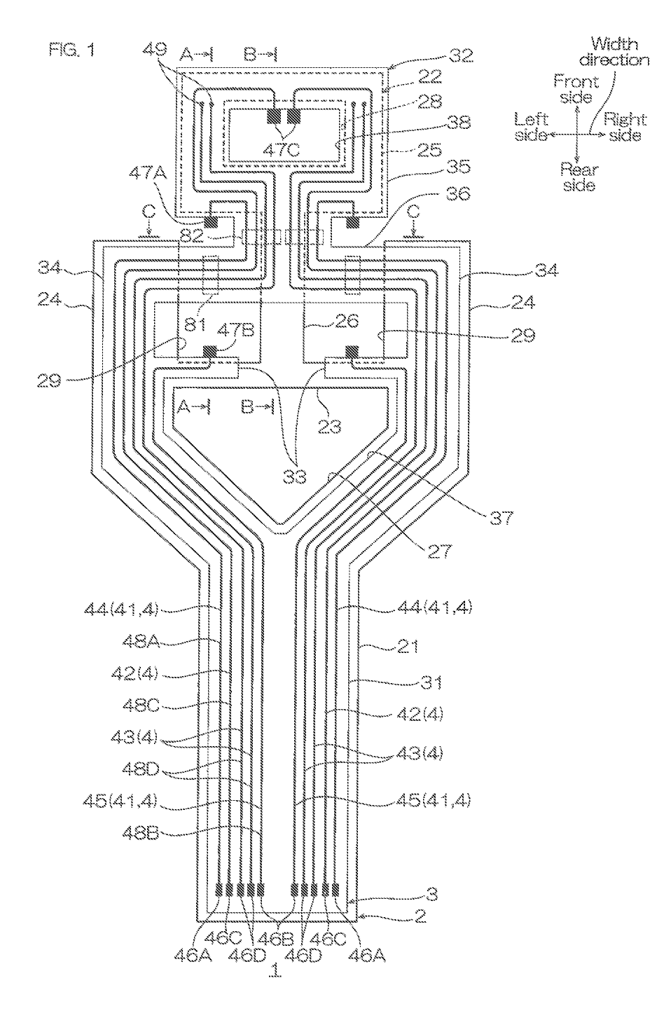

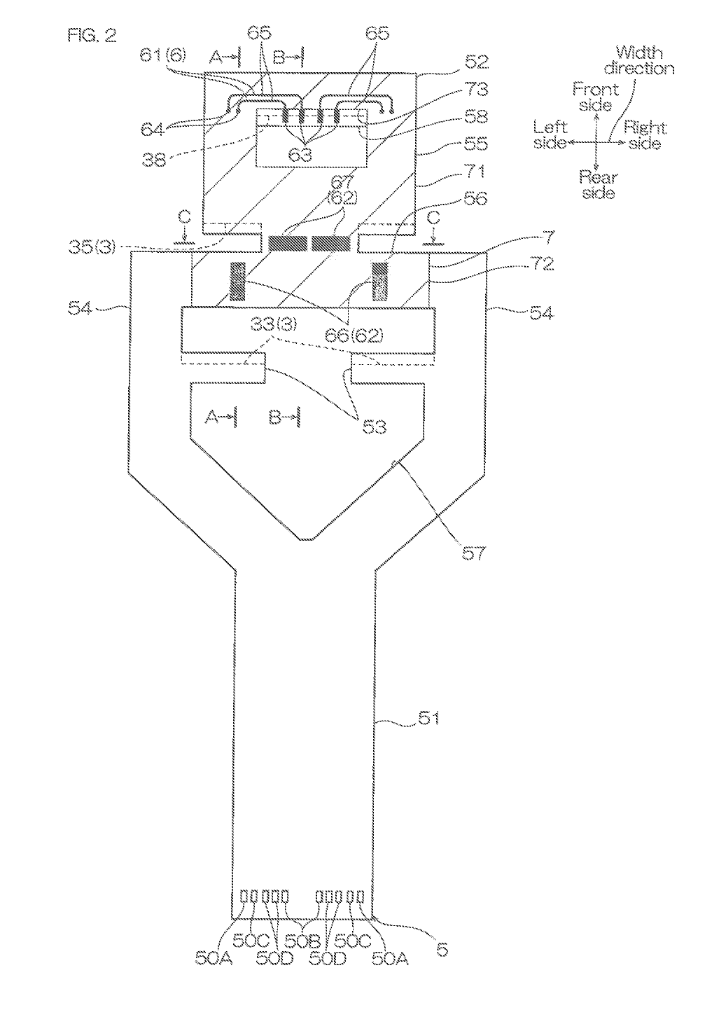

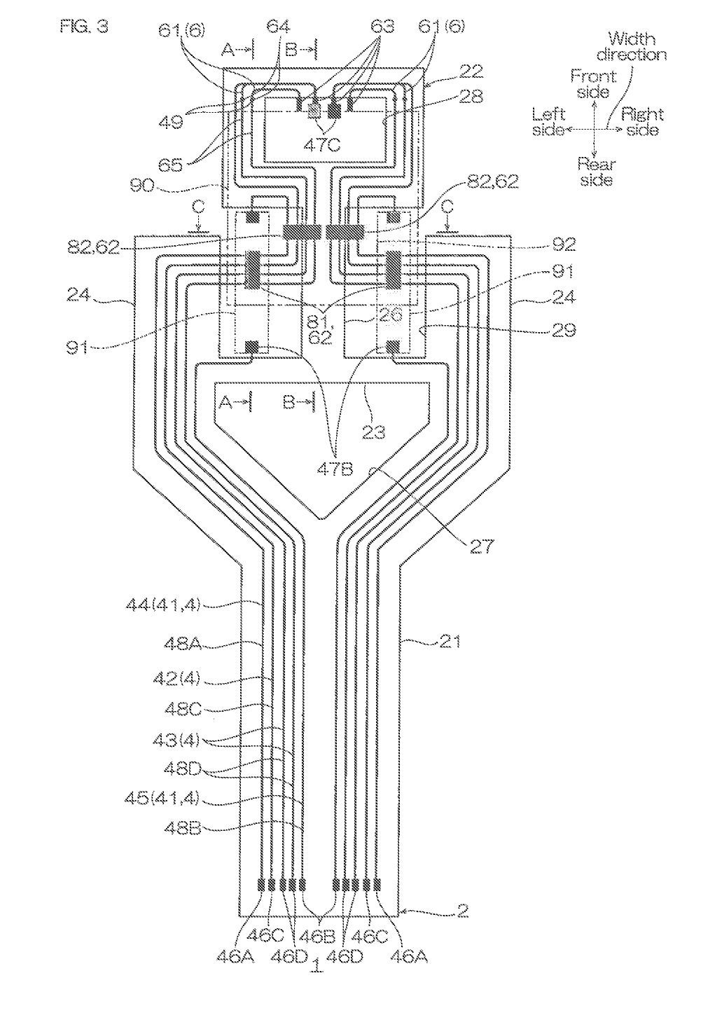

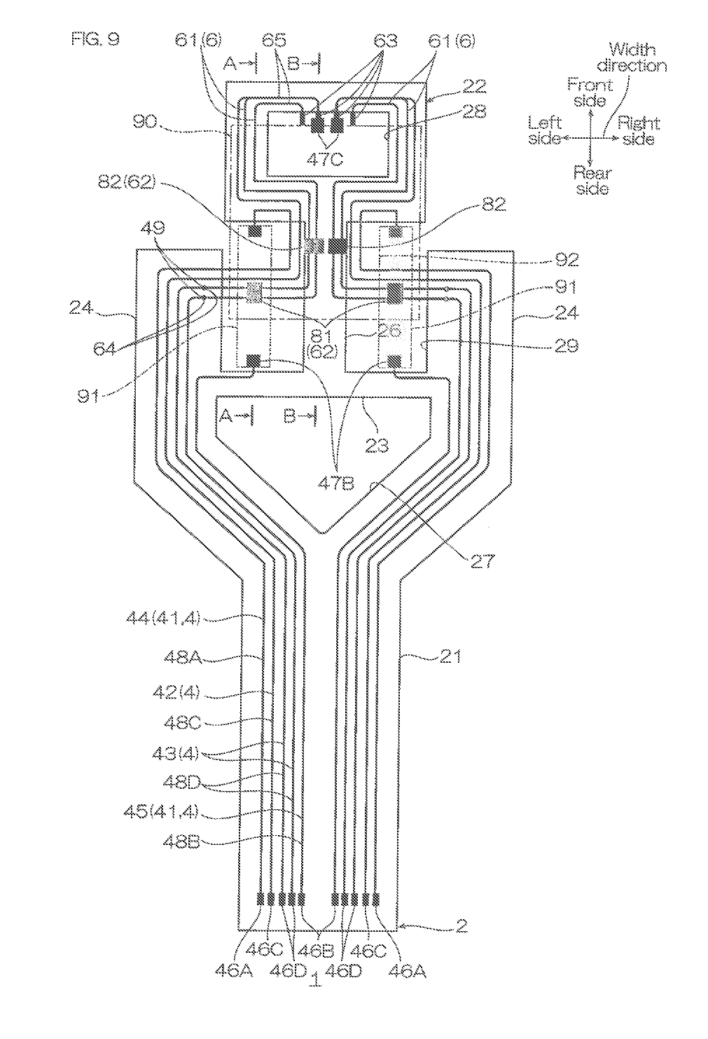

In FIG. 1, up-down direction on the plane of the sheet is front-rear direction (first direction), the upper side on the plane of the sheet is front side (one side in first direction), and the lower side on the plane of the sheet is rear side (the other side in first direction). The left-right direction on the plane of the sheet is left right direction (width direction, second direction), the left side on the plane of the sheet is left side (one side in width direction, one side in second direction), and the right side on the plane of the sheet is right side (the other side in width direction, the other side in second direction). The paper thickness direction on the plane of the sheet is up down direction (thickness direction, third direction), the near side on the plane of the sheet is upper side (one side in thickness direction, one side in third direction), and the far side on the plane of the sheet is lower side (the other side in thickness direction, the other side in third direction). To be specific, the directions are based on direction arrows in the figures. In FIG. 1, the intermediate insulating layer 5, second conductive pattern 6, and insulating cover layer 7 are omitted. In FIG. 2, the metal supporting board 2 and first conductive pattern 4 are omitted, and the insulating cover layer 7 is shown with grid hatching. In FIG. 3, the insulating layers (insulating base layer 3, intermediate insulating layer 5, and insulating cover layer 7) are omitted. In FIG. 9, the insulating layers (insulating base layer 3, intermediate insulating layer 5, and insulating cover layer 7) are omitted.

### First Embodiment

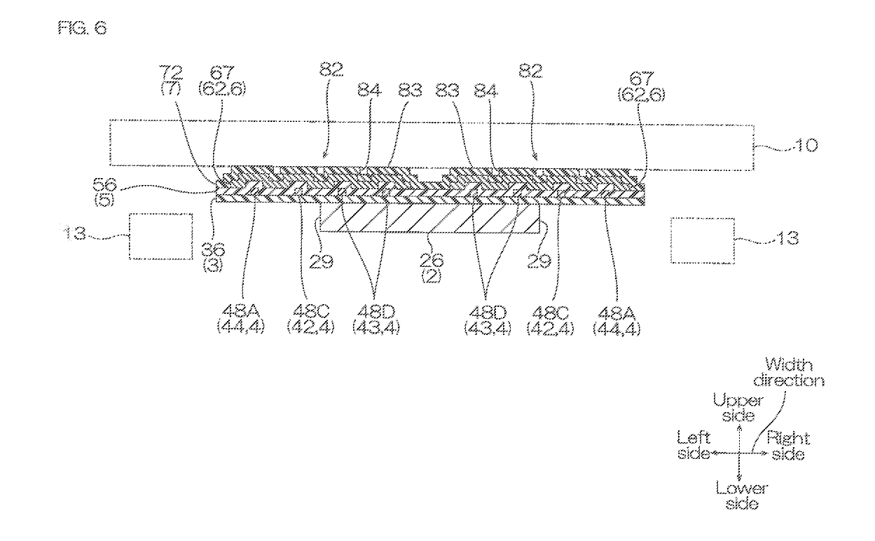

With reference to FIG. 1 to FIG. 8I, a suspension hoard with circuits 1 of a first embodiment of the present invention is described.

In the suspension board with circuits 1, a slider unit 12 on which a slider 10 and a light emitting element 11 are mounted, and a piezoelectric element 13 as a piezoelectric element are mounted, and the suspension board with circuits 1 is mounted in a hard disk drive (not shown) in which heat assisted method is used.

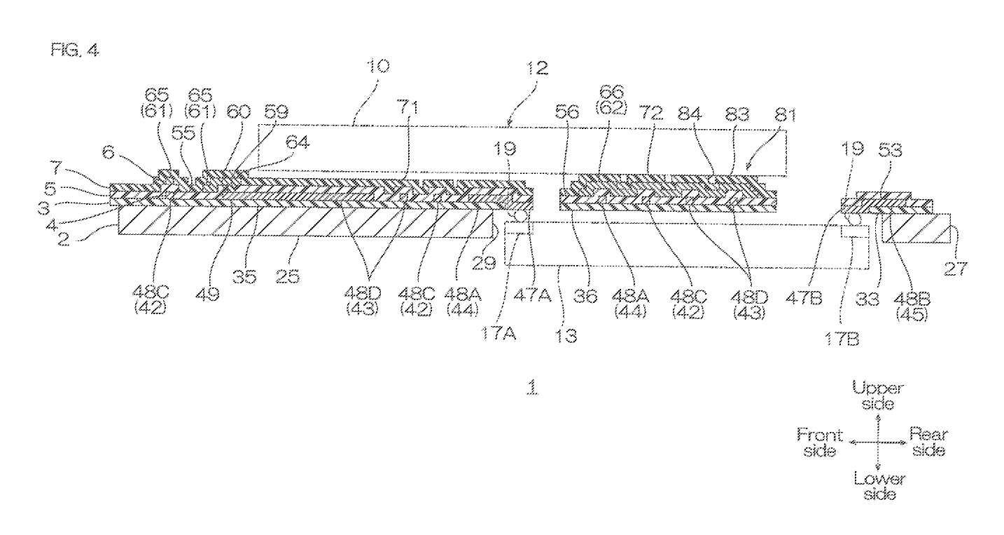

The suspension board with circuits 1 is, as shown in FIGS. 1 to 3, formed into a flat belt shape extending in front-rear direction. The suspension board with circuits 1 includes, as shown in FIGS. 4 to 6, a metal supporting board 2 as a metal support layer, an insulating base layer 3 disposed on the metal supporting board 2 as a first insulating layer, a first conductive pattern 4 disposed on a insulating base layer 3 as a first metal layer, an intermediate insulating layer 5 disposed on the first conductive pattern 4 as a second insulating layer, a second conductive pattern 6 disposed on the intermediate insulating layer 5 as a second metal layer, and an insulating cover layer 7 disposed on the second conductive pattern 6 as a third insulating layer.

The metal supporting board 2 is, as shown in FIGS. 1 and 3, formed into a flat belt shape extending into froth-rear direction, and integrally includes a main body portion 21 and a gimbal portion 22 formed at the front side of the main body portion 21.

The main body portion 21 is formed into a generally rectangular shape in plan view at the rear side portion extending into front-rear direction, and at the front side portion thereof, it is formed into a generally letter Y shape in plan view, splitting obliquely toward widthwise outer side. The main body portion 21 is supported by a load beam (not shown) of the hard disk drive when the suspension board with circuits 1 is mounted on the hard disk drive.

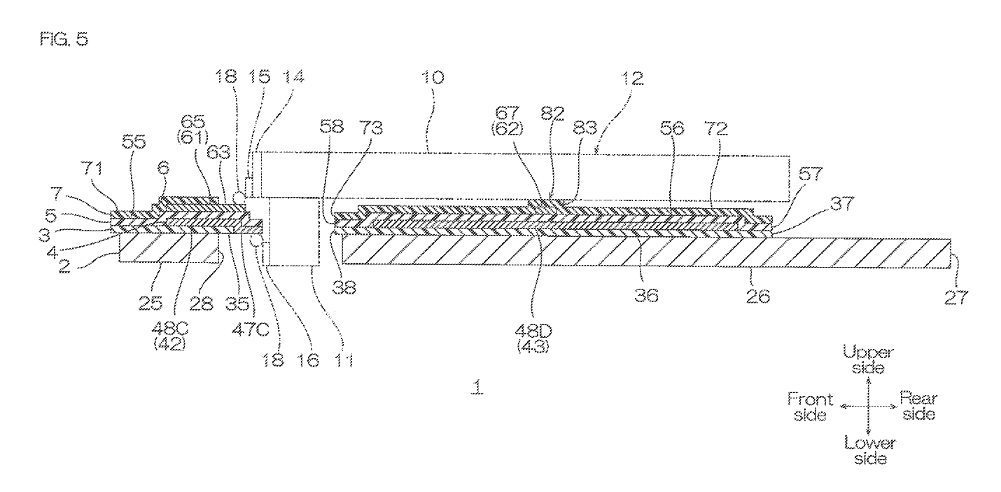

The gimbal portion 22 extends continuously from the front end of the math body portion 21 to the front side, and is formed into a generally rectangular shape having a width larger than that of the main body portion 21 in plan view. The slider unit 12 (ref: phantom line shown in FIGS. 4 to 5) and the piezoelectric element 13 (ref: phantom line shown in FIG. 4) are mounted on the gimbal portion 22.

The gimbal portion 22 includes a gimbal rear portion 23, a pair of outrigger portions 24, a mount portion 25, and a connection portion 26.

The gimbal rear portion 23 has a generally rectangular shape in plan view extending in width direction (left-right direction), and is connected in front-rear direction to the front end edge of the main body portion 21 at both widthwise outer sides. In this manner, a main body opening 27 is formed between the gimbal rear portion 23 and the main body portion 21.

The outrigger portion 24 has a generally rectangular shape in plan view extending in front-rear direction, and is formed as a pair extending linearly from the both widthwise end portions of the gimbal rear portion 23 toward the front side.

The mount portion 25 is formed into a generally rectangular shape in plan view. The mount portion 25 is disposed at the front side of the gimbal rear portion 23, in spaced apart relation from the gimbal rear portion 23. The mount portion 25 is disposed so that the rear-end edge of the mount portion 23 is positioned at the front side of the front end edge of the pair of outrigger portions 24.

A front opening 28 for mounting the slider unit 12 is formed at generally a center portion in plan view of the mount portion 25. The front opening 28 is formed into a generally rectangular shape in plan view so as to penetrate the metal supporting board 2 in thickness direction.

The connection portion 26 is formed into a generally rectangular shape in plan view extending in front-rear direction. The connection portion 26 is formed so as to bridge the front end edge of the gimbal rear portion 23 and the rear end edge of the mount portion 25 from the widthwise center of the gimbal rear portion 23 toward the front side. The connection portion 26 is disposed in spaced apart relation at widthwise inner side of the pair of outrigger portions 24.

In this manner, a pair of center openings 29 for mounting a pair of piezoelectric elements 13 are formed between the mount portion 25 and the gimbal rear portion 23, and between the connection portion 26 and the pair of outrigger portions 24.

As shown in FIG. 3 and FIG. 8H, the slider mounting region 90 is the region that overlaps with the slider unit 12 when the slider unit 12 is projected in thickness direction at the time of mounting it on the suspension board with circuits 1. The slider mounting region 90 is, specifically, is a region in front-rear direction of the metal supporting board 2, from the front side portion of the front opening 28 (to be more specific, rear-end edge of head connection terminals 63 to be described later) to the rear side portion of the connection portion 26, and in the width direction of the metal supporting board 2, is a region positioned at the slightly widthwise inner side of the mount portion 25.

The piezoelectric element mounting region 91 as a piezoelectric element mounting region is, as shown in FIG. 3 and FIG. 8I, a region overlapping with the pair of piezoelectric elements 13 when the pair of piezoelectric elements 13 are projected in thickness direction upon mounting it on the suspension board with circuits 1. A plurality of (two) piezoelectric element mounting regions 91 are defined in spaced apart relation from each other in width direction. To be specific, the piezoelectric element mounting regions 91 are regions positioned at generally a center portion in plan view of the pair of center openings 29 (to be more specific, from front end edge of the front piezoelectric element connection terminal 47A to rear-end edge of the rear piezoelectric element connection terminal 47B to be described later).

A piezoelectric element non-mounting region 92 is a region that does not overlap with the pair of piezoelectric elements 13 where the pair of piezoelectric elements 13 are projected in thickness direction upon mounting it on the suspension board with circuits 1. To be specific, it is the entire region excluding piezoelectric element mounting region 91.

The metal supporting board 2 is formed from, for example, metal materials such as stainless steel, 42alloy, and aluminum. Preferably, it is formed from stainless steel.

The metal supporting board 2 has a thickness of, for example, 5 μm or more, preferably 10 μm or more, and for example, 35 μm or less, preferably 30 μm or less.

The insulating base layer 3 is, as shown in FIG. 1, formed on the upper face (surface in one side in thickness direction) of the metal supporting board 2. The insulating base layer 3 integrally includes a main body portion insulating base layer 31 corresponding to the main body portion 21, and a gimbal portion insulating base layer 32 corresponding to the gimbal portion 22.

The main body portion insulating base layer 31 extends from the rear end portion toward the front side in the main body portion 21 so as to correspond to the pattern of a first conductive pattern 4 (described later) to be formed, and is formed into a generally letter Y shape in plan view, splitting obliquely toward the front side and widthwise outer sides at the front end portion of the main body portion 21.

The gimbal portion insulating base layer 32 includes a pair of rear insulating base layers 33 corresponding to the gimbal rear portion 23, a pair of outer insulating base layers 34 corresponding to the pair of outrigger portions 24, a front-insulating base layer 35 corresponding to the mount portion 25, and an inner-insulating base layer 36 corresponding to the connection portion 26.

The pair of rear insulating base layers 33 are formed into a generally rectangular shape in plan view in spaced apart relation from each other in width direction so as to extend inward continuously from the front end edge of the main body portion insulating base layer 31.

The pair of outer insulating base layers 34 are formed into a generally rectangular shape in plan view so as to extend toward the front side continuously from the front end edge of the widthwise outside portion of the pair of rear insulating base layer 33 in spaced apart relation from each other in width direction.

The front-insulating base layer 35 is formed into a generally rectangular shape in plan view. The front-Insulating base layer 35 is formed so that its peripheral edge is slightly outside of the peripheral edge of the mount portion 25 of the metal supporting board 2. That is, the front end edge of the front-insulating base layer 35 is positioned at the front side of the front end edge of the mount portion 25, and the rear-end edge of the front-insulating base layer 35 is positioned at the rear side of the rear-end edge of the mount portion 25, and the left-end edge of the front-insulating base layer 35 is positioned at the left side of the left-end edge of the mount portion 25, and the right-end edge of the front-insulating base layer 35 is positioned at the right side of the right-end edge of the mount portion 25.

At a generally center in plan view of the front-insulating base layer 35, a front insulating base opening 38 is formed.

The front insulating base opening 38 is formed into a generally rectangular shape in plan view at the portion overlapping with the front opening 28 when projected in thickness direction so as to penetrate the front-insulating base layer 35 in thickness direction.

The front insulating base opening 38 is formed so that its peripheral edge is slightly inside the peripheral edge of the front opening 28. That is, the front end edge of the front insulating base opening 38 is positioned at the rear side of the front end edge of the front opening 28, the rear-end edge of the front insulating base opening 38 is positioned at the front side of the rear-end edge of the front opening 28, the left-end edge of the front insulating base opening 38 is positioned at the right side of the left-end edge of the front opening 28, and the right-end edge of the front insulating base opening 38 is positioned at the left side of the right-end edge of the front opening 28.

The inner-insulating base layer 36 is formed into a generally inversed letter T shape in plan view so as to bridge the front-insulating base layer 35 and the pair of outer insulating base layers 34. That is, the inner-insulating base layer 36 is formed so that it extends from the rear-end edge of the front-insulating base layer 35 at the widthwise center toward the rear side, splits widthwise and outward into two, and reaches the widthwise inner end edge of the front side portion of the pair of outer insulating base layers 34.

In the insulating base layer 3, a rear insulating base opening 37 is formed between the main body portion insulating base layer 31, the rear insulating base layer 33, the pair of outer insulating base layers 34, and the inner-insulating base layer 36. The rear insulating base opening 37 is formed so as to include the main body opening 27 when projected in thickness direction.

The insulating base layer 3 is formed from insulating materials such as, for example, synthetic resin including polyimide resin, polyamide-imide resin, acrylic resin, polyethernitrile resin, polyether sulfone resin, polyethylene terephthalate resin, polyethylenenaphthalate resin, and polyvinyl chloride resin. Preferably, it is formed from polyimide resin.

The insulating base layer 3 has a thickness of, for example, 1 μm or more, preferably 3 μm or more, and for example, 35 μm or less, preferably 33 μm or less.

The first conductive pattern 4 is formed, as shown in FIG. 1, on the upper face of the insulating base layer 3. The first conductive pattern 4 includes a piezoelectric element connection circuit 41, light emitting element connection circuit 42, and a first head connection circuit 43.

The piezoelectric element connection circuit 41 includes a front piezoelectric element connection circuit 44 and a rear piezoelectric element connection circuit 45.

The front piezoelectric element connection circuit 44 includes first power source terminals 46A, front piezoelectric element connection terminals 47A, and first power source wires 48A.

The plurality of (two) first power source terminals 46A are provided, and are disposed at the rear end portion of the main body portion insulating base layer 31. Of the plurality of (ten) terminals provided on the main body portion insulating base layer 31, the first power source terminals 46A are disposed one by one at widthwise outermost side in spaced apart relation from each other. The first power source terminals 46A are foamed into a generally rectangular shape in plan view. The first power source terminals 46A are electrically connected to a power source for piezoelectric elements (not shown).

The plurality of (two) front piezoelectric element connection terminals 47A are provided, and are disposed at front end portion of the pair of piezoelectric elements mounting region 91. To be specific, the front piezoelectric element connection terminals 47A are formed into a generally rectangular shape in plan view so as to extend from the rear-end edge of widthwise outside portion of the front-insulating base layer 35 to rear side, and are disposed in spaced apart relation from each other in width direction. The front piezoelectric element connection terminals 47A are formed, as shown in FIG. 4, so as to slightly extend from rear-end edge of the front-insulating base layer 35 to lower side, and then extend to rear side.

The plurality of (two) first power source wires 48 A are provided, as shown in FIG. 1. Of the plurality of (ten) wires provided on the insulating base layer 3, the first power source wire 48A are disposed one by one at widthwise outermost side in spaced apart relation from each other in width direction. The first power source wires 48A are formed so that one end thereof is continuous with the first power source terminals 46A, and the other end thereof is continuous with the front piezoelectric element connection terminals 47A. To be specific, the first power source wires 48A are formed so as to extend frontward from the first power source terminals 46A in the main body portion insulating base layer 31; bend widthwise outwardly at the front end portion of the main body portion insulating base layer 31; bend frontward at both widthwise end portions thereof; extend frontward on the rear insulating base layer 33 and the outer insulating base layer 34; bend widthwise inwardly at the front end portion of the outer insulating base layer 34; bend frontward at widthwise center of the inner-insulating base layer 36; bend widthwise outwardly at the rear end portion of the front-insulating base layer 35; turn back to rear side en route on width direction at the rear end portion; and reach the front piezoelectric element connection terminals 47A.

The first power source wires 48A electrically connect the first power source terminals 46A to the front piezoelectric element connection terminals 47A. The first power source wires 48A supply electric power from the power source for piezoelectric elements to the piezoelectric element 13 through the first power source terminals 46A.

The rear piezoelectric element connection circuit 45 includes second power source terminals 46B, rear piezoelectric element connection terminals 47B, and second power source wires 48B.

The plurality of (two) second power source terminals 46B are provided, and are disposed at rear end portion of the main body portion insulating base layer 31. Of the plurality of (ten) terminals, the second power source terminals 46B are disposed one by one in spaced apart relation from each other at widthwise innermost side. The second power source terminals 46B are formed into a generally rectangular shape in plan view. The second power source terminals 46B are electrically connected to a power source for piezoelectric elements (not shown).

A plurality of (two) rear piezoelectric element connection terminals 47B are provided, and are disposed at rear end portion of the pair of piezoelectric elements mounting regions 91. To be specific, the rear piezoelectric element connection terminals 47B are formed into a generally rectangular shape in plan view so as to extend from the front end edge of widthwise inner side of the rear insulating base layer 33 to front side in plan view, and are disposed in spaced apart relation from each other in width direction. The rear piezoelectric element connection terminals 47B are formed, as shown in FIG. 4, so as to slightly extend from front end edge of the rear insulating base layer 33 to lower side, and then extend frontward.

The plurality of (two) second power source wires 48B are provided, as shown in FIG. 1. Of the plurality of (ten) wires 48, the second power source wires 48B are disposed one by one in spaced apart relation from each other in width direction at widthwise innermost side. The second power source wires 48B are formed so that one end thereof is continuous with the second power source terminals 46B, and the other end thereof is continuous with the rear piezoelectric element connection terminals 47B. To be specific, the second power source wires 48B are formed so as to extend along the first power source wires 48A in the main body portion insulating base layer 31 and rear insulating base layer 33; bend widthwise inwardly at the rear insulating base layer 33; bend frontward at inner portion of the rear insulating base layer 33; and reach the rear piezoelectric element connection terminal 47B.

The second power source wires 48B electrically connect the second power source terminals 46B to the rear piezoelectric element connection terminal 47B. The second power source wire 48B supply electric power from the power source for piezoelectric elements (not shown) to the piezoelectric element 13 through the second power source terminals 46B.

The light emitting element connection circuit 42 includes third power source terminals 46C, light emitting element connection terminal 47C, and third power source wire 48C.

The plurality of (two) third power source terminals 46C are provided, and are disposed at rear end portion of the main body portion insulating base layer 31. The third power source terminals 46C are disposed one by one in spaced apart relation from each other at widthwise inner side of the plurality of (two) first power source terminals 46A. The third power source terminals 46C are electrically connected to a power source for light emitting element (not shown).

The plurality of (two) light emitting element connection terminals 47C are provided, and are disposed at front end portion of the front insulating base opening 38. To be specific, the light emitting element connection terminals 47C are formed into a generally rectangular shape in plan view so as to extend from front end edge of the front insulating base opening 38 to rear side, and are disposed in spaced apart relation from each other in width direction. The light emitting element connection terminals 47C are formed, as shown in FIG. 5, so as to slightly extend from front end edge of the front insulating base opening 38 to lower side, and then extend to rear side.

The plurality of (two) third power source wires 48C are provided, as shown in FIG. 1. The third power source wires 48C are disposed one by one in spaced apart relation from each other in width direction at widthwise inner side of the plurality of (two) first power source wires 48A, to be more specific, at widthwise inner side adjacent to the plurality of (two) first power source wires 48A. The third power source wires 48C are formed so that one end thereof is continuous with the third power source terminals 46C, and the other end thereof is continuous with the light emitting element connection terminals 47C. To be specific, the third power source wires 48C are formed so as to extend along the first power source wire 48A in the main body portion insulating base layer 31, rear insulating base layer 33, outer insulating base layer 34, and inner-insulating base layer 36; bend outwardly in width direction at the rear end portion of the front-insulating base layer 35; bend frontward along the peripheral end of the front-insulating base layer 35 at its outer end portion; bend inwardly at its front end portion; turn back to rear side at the inner portion; and reach the light emitting element connection terminal 47C.

Third power source wires 48C electrically connect the third power source terminals 46C to the light emitting element connection terminals 47C. The third power source wires 48C supply electric power from the power source for light emitting element (not shown) to the light mining device 11 through the third power source terminals 46C.

The first head connection circuit 43 includes, as shown in FIG. 1, the signal terminals 46D, lower connecting portion 49, and lower signal wire 48D.

The plurality of (four) signal terminals 46D are provided, and are disposed at rear end portion of the main body portion insulating base layer 31. The signal terminals 46D are disposed two by two in spaced apart relation from each other at widthwise inner side of the plurality of (two) third power source terminals 46C and widthwise outer side of the plurality of (two) second power source terminals 46B. The signal terminals 46D are electrically connected to a read/write board (not shown).

A plurality of (four) lower connecting portions 49 are disposed in spaced apart relation from each other in width direction at front side portion of the front-insulating base layer 35. The lower connecting portions 49 are formed into a generally circular shape (circle land shape) in plan view, and are disposed so as to include through holes 59 (described later) when projected in thickness direction. The upper end portion of the lower connecting portions 49 is continuous with, as shown in FIG. 4, lower end of the via conductive portion 60 (described later).

The plurality of (four) lower signal wires 48D are provided, as shown in FIG. 1. The lower signal wires 48D are disposed two by two at widthwise inner side of the plurality of (two) third power source wires 48C and widthwise outside of the plurality of (two) second power source wires 48B in spaced apart relation from each other in width direction. The lower signal wires 48D are formed so that one end thereof is continuous with the signal terminals 46D, and the other end thereof is continuous with the lower connecting portions 49. To be specific, the lower signal wires 48D are formed so as to extend along the third power source wires 48C on the main body portion insulating base layer 31, rear insulating base layer 33, outer insulating base layer 34, and inner-insulating base layer 36; bend outwardly in width direction at the rear side portion of the front-insulating base layer 35; bend frontward at widthwise outside; and reach the lower connecting portion 49.

The lower signal wires 48D electrically connect the signal terminals 46D to the lower connecting portions 49. The lower signal wires 48D transmit electric signals between the magnetic head 14 and the read/write board (not shown) through the signal terminals 46D and the second head connection circuit 61 (described later).

The first conductive pattern 4 is formed from, for example, metal conductive materials such as copper, nickel, gold, solder, or alloys thereof, preferably, copper.

The first conductive pattern 4 has a thickness of, for example, 1 μm or more, preferably 3 μm or more, and for example, 25 μm or less, preferably 20 μm or less.

The wires 48 (48A to 48D) have a width of, for example, 5 μm or more, preferably 8 μm or more, and for example, 200 μm or less, preferably 100 μm or less.

The gap between the plurality of wires 48 is, for example, 5 μm or more, preferably 8 μm or more, and for example, 1000 μm or less, preferably 100 μm or less.

The terminals (46A to 46D, 47A to 47C) have a width and a length (length in front-rear direction) of, for example, 10 μm or more, preferably 20 μm or more, and for example, 1000 μm or less, preferably 800 μm or less.

The lower connecting portion 49 has a diameter of, for example, 30 μm or more, preferably 40 μm or more, and for example, 200 μm or less, preferably 150 μm or less.

The intermediate insulating layer 5 is formed on the upper face of the first conductive pattern 4 and insulating base layer 3, as shown in FIG. 2 and FIGS. 4 to 6. To be specific, the intermediate insulating layer 5 is disposed on the upper face of the insulating base layer 3 so as to cover the upper face and side faces of the wires (48A to 48D), and to expose the upper face of the first to third power source terminals 46A to 46C and signal terminals 46D. The intermediate insulating layer 5 is formed so as to be generally the same as the insulating base layer 3 in plan view. That is, the intermediate insulating layer 5 integrally includes a main body portion intermediate insulating layer 51 corresponding to the main body portion insulating base layer 31, and a gimbal portion intermediate insulating layer 52 corresponding to the gimbal portion insulating base layer 32. The gimbal portion intermediate insulating layer 52 includes a pair of rear intermediate insulating layers 53 corresponding to the pair of rear insulating base layers 33, a pair of outer intermediate insulating layers 54 corresponding to the pair of outer insulating base layers 34, front intermediate insulating layer 55 corresponding to the front-insulating base layer 35, and inner intermediate insulating layer 56 corresponding to the inner-insulating base layer 36.

Between the main body portion intermediate insulating layer 51, the pair of rear intermediate insulating layers 53, a pair of outer intermediate insulating layers 54, and inner intermediate insulating layer 56, rear intermediate insulating opening 57 corresponding to the rear insulating base opening 37 is formed. The rear intermediate insulating opening 57 is disposed so as to include the main body opening 27 when projected in thickness direction.

At a generally center in plan view of the front intermediate insulating layer 55, a front intermediate insulating opening 58 corresponding to the front insulating base opening 38 is formed. The front intermediate insulating opening 58 is formed into a generally rectangular shape in plan view at the portion overlapping with the front opening 28 when projected in thickness direction so as to penetrate the front intermediate insulating layer 55 in thickness direction.

The intermediate insulating layer 5 is formed so as to cover, in the proximity of the front piezoelectric element connection terminal 47A, rear piezoelectric element connection terminal 47B, and light emitting element connection terminal 47C, the upper face of these connection terminals. To be specific, as shown in FIG. 4, the rear intermediate insulating layer 53 is formed so that front end edge of its inner portion is positioned at front side of the front end edge of the inner portion of the rear insulating base layer 33, and coincides with front end edge of the rear piezoelectric element connection terminal 47B. The front intermediate insulating layer 55 is formed so that the rear-end edge of the outer portion is positioned at rear side of the rear-end edge of outer portion of the front-insulating base layer 35, and coincides with the rear-end edge of the front piezoelectric element connection terminals 47A. As shown in FIG. 5, the front intermediate insulating opening 58 is formed so that its front end edge is positioned at rear end of the front end edge of the front insulating base opening 38, and coincides with the rear-end edge of the light emitting element connection terminal 47C.

In the front intermediate insulating layer 55, as shown in FIG. 4, a plurality of (four) through holes 59 penetrating the front intermediate insulating layer 55 in thickness direction are formed. The through holes 59 are disposed in spaced apart relation from each other in width direction at outer portion of the front intermediate insulating opening 58. The through holes 59 are formed into a generally circular shape in plan view having a smaller diameter than that of the lower connecting portion 49 at the portion overlapping with the lower connecting portion 49 when projected in thickness direction. That is, through holes 59 are formed so as to be included in the lower connecting portion 49 when projected in thickness direction.

A via conductive portion 60 is provided in the through holes 59. To be specific, the via conductive portion 60 is disposed so as to fill the entire through holes 59. The via conductive portion 60 is formed into a cylindrical shape having a smaller diameter than that of the lower connecting portion 49.

The via conductive portion 50 is formed from, for example, a metal conductive material that is the same as that of the first conductive pattern 4, preferably, formed from copper.

On the main body portion intermediate insulating layer 51 as shown in FIG. 2, a plurality of (ten) terminal openings 50 for exposing the upper face of the terminal are formed. The terminal openings 50 are formed in spaced apart relation from each other in width direction in plan view. To be specific, a plurality of (two) first terminal openings 50A exposing the upper face of the first power source terminals 46A are formed at widthwise outermost side. A plurality of (two) third terminal openings 50C exposing the upper face of the third power source terminals 46C are formed at widthwise inner side thereof in spaced apart relation. A plurality of (four) fourth terminal openings 50D exposing the upper face of the signal terminals 46D are formed at widthwise inner side thereof in spaced apart relation. A plurality of (two) second terminal openings 50B exposing the upper face of the second power source terminals 46B are formed in spaced apart relation at widthwise inner side thereof.

The intermediate insulating layer 5 is formed from the same insulating material as that of the insulating base layer 3. The intermediate insulating layer 5 has a thickness of, for example, 1 μm or more, preferably 3 μm or more, and for example, 40 μm or less, preferably 10 μm or less.

The second conductive pattern 6 is formed, as shown in FIG. 2, on the upper face of the intermediate insulating layer 5. The second conductive pattern 6 includes a second head connection circuit 61 and a metal sheet portion 62.

The second head connection circuit 61 includes head connection terminals 63, upper connecting portion 64, and upper signal wires 65.

The plurality of (four) head connection terminals 63 are provided, and are disposed at front side of the slider mounting region 90 in plan view. To be specific, the head connection terminals 63 are disposed at front side of the front end edge of the front intermediate insulating opening 58. The head connection terminals 63 are formed into a generally rectangular shape in plan view extending in front-rear direction, and are disposed in spaced apart relation from each other in width direction. The head connection terminals 63 are disposed, as shown in FIGS. 3 and 5, so as to overlap with the light emitting element connection terminals 47C when projected in thickness direction. To be specific, the head connection terminals 63 are disposed so that the rear end portion of the inner two head connection terminals 63 out of the four head connection terminals 63 overlap with the light emitting element connection terminals 47C when projected in thickness direction.

The plurality of (four) upper connecting portions 64 are disposed, as shown in FIGS. 3 and 4, in spaced apart relation from each other in width direction at front side portion of the front intermediate insulating layer 55 and widthwise outside of the front intermediate insulating opening 58. The upper connecting portions 64 are formed into a generally circular shape (circle land shape) in plan view, and are disposed so as to include the through hole 59 when projected in thickness direction. The lower end of the upper connecting portions 64 is continuous with upper end portion of the via conductive portion 60, as shown in FIG. 4.

The upper signal wires 65 are formed so that one end thereof is continuous with the upper connecting portions 64, and the other end thereof is continuous with the head connection terminals 63, as shown in FIG. 2. To be specific, the upper signal wires 65 are formed so as to slightly extend to the front side along the peripheral end of the front intermediate insulating layer 55 at the front side portion of the front intermediate insulating layer 55; bend inwardly at its front end portion; turn back to rear side at inner portion; and reach the head connection terminals 63.

In this manner, the head connection terminals 63 are electrically connected to the signal terminals 46D through the upper signal wires 65, upper connecting portions 64, via conductive portion 60, lower connecting portion 49, and lower signal wire 48D.

The metal sheet portion 62 includes a plurality of (two) first metal sheet portions 66 and a plurality of (two) second metal sheet portions 67.

The first metal sheet portions 66 are disposed, as shown in FIGS. 2 and 3, in the slider mounting region 90 and piezoelectric element mounting region 91 (slider and piezoelectric element mounting region). To be specific, the first metal sheet portions 66 are disposed at widthwise outer side portion of the inner intermediate insulating layer 56 in spaced apart relation from each other in width direction.

The first metal sheet portions 66 have a generally rectangular sheet shape in plan view extending in plane direction (front-rear direction and width direction). The first metal sheet portions 66 are disposed so as to include the first power source wire 48A, third power source wire 48C, and two lower signal wires 48D when projected in thickness direction. That is, the first metal sheet portions 66 are disposed across the first power source wire 48A, third power source wire 48C, and lower signal wire 48D in front-rear direction that is crossing (orthogonal) these.

The second metal sheet portion 67 is disposed in the slider mounting region 90 and piezoelectric element non-mounting region 92 (slider mounting and piezoelectric element non-mounting region). To be specific, the second metal sheet portion 67 is disposed at front end portion of the inner intermediate insulating layer 56 in spaced apart relation from each other in width direction.

The second metal sheet portion 67 has a generally rectangular sheet shape in plan view extending in plane direction (front-rear direction and width direction). The second metal sheet portion 67 is disposed so as to include the first power source wire 48A, third power source wire 48C, and two lower signal wires 48D when projected in thickness direction. That is, the second metal sheet portion 67 is disposed across the first power source wire 48A, third power source wire 48C, and lower signal wire 48D in width direction crossing (orthogonal) these.

The metal sheet portion 62 is independent electrically. That is, the metal sheet portion 62 is not electrically connected to the conductive pattern of the wires (48A to 48D, 65) and terminals (46A to 46D, 49, 63, 64), and is a component independent from other components of the second conductive pattern 6 and first conductive pattern 4.

The second conductive pattern 6 is formed from a metal conductive material that is the same as the first conductive pattern 4, and preferably, it is formed from copper.

The second conductive pattern 6 has a thickness of, for example, 1 μm or more, preferably 3 μm or more, and for example, 25 μm or less, preferably 20 μm or less.

The upper signal wires 65 have a width of, for example, the same as that of the wires of the first conductive pattern 4.

The width of the upper signal wires 65, and, the interval between the upper signal wires 65 and the wires 48 of the first conductive pattern 4 is, for example, the same as the width of the wires 48 of the first conductive pattern 4.

The head connection terminals 63 have a width and a length of (length in front-rear direction), for example, the width and length of the terminal of the first conductive pattern 4.

The upper connecting portions 64 have a diameter of, for example, the same as that of the lower connecting portion 49.

The maximum plane direction length (length in front-rear direction and width direction) of the metal sheet portion 62 is, for example, 5 μm or more, preferably 10 μm or more, and for example, 1000 μm or less, preferably 800 μm or less.

The insulating cover layer 7 is formed on the upper face of the second conductive pattern 6 and intermediate insulating layer 5 as shown in FIG. 2 and FIGS. 4 to 6. To be specific, the insulating cover layer 7 is disposed at the upper face of the intermediate insulating layer 5 so as to cover the upper face and side faces of the upper signal wires 65 and upper connecting portions 64 and to expose the upper face and side faces of the head connection terminals 63. The insulating cover layer 7 is formed so as to be substantially the same as a portion of the intermediate insulating layer 5 in plan view. That is, the insulating cover layer 7 integrally includes a front-insulating cover layer 71 corresponding to the front intermediate insulating layer 55, and an inner-insulating cover layer 72 corresponding to the inner intermediate insulating layer 56.

At a generally center in plan view of the front-insulating cover layer 71, a cover insulating opening 73 corresponding to the front intermediate insulating opening 58 is formed. The cover insulating opening 73 is formed into a generally rectangular shape in plan view so as to penetrate the front-insulating cover layer 71 in thickness direction at a portion overlapping with the front opening 28 when projected in thickness direction. As shown in FIG. 5, the cover insulating opening 73 is formed so that its front end edge is positioned at the front side of the front end edge of the front insulating base opening 38 and front intermediate insulating opening 58, and it coincides with the front end edge of the head connection terminals 63C. In this manner, the cover insulating opening 73 allows the bead connection terminals 63 disposed on the front intermediate insulating layer 55 to expose from the front-insulating cover layer 71.

The insulating cover layer 7 is formed from the same insulating material as that is fanning the insulating base layer 3. The insulating cover layer 7 has a thickness of, for example, 1 μm or more, preferably 3 μm or more, and for example, 40 μm or less, preferably 10 μm or less.

The pedestals 80 are described next. The pedestals 80 include a plurality of (two) first pedestals 81 and a plurality of (two) second pedestals 82.

The first pedestals 81 are provided in the slider mounting region 90 and piezoelectric element mounting region 91 (slider mounting and piezoelectric element mounting region). To be specific, the first pedestals 81 are formed in a widthwise outer side region of the inner-insulating cover layer 72 in spaced apart relation from each other in width direction.

The first pedestals 81 include the insulating base layer 3, plurality of (four) wires (48A, 48C, 48D), intermediate insulating layer 5, first metal sheet portion 66, and insulating cover layer 7 in this sequence. To be more specific, the first pedestals 81 include the inner-insulating base layer 36, plurality of (four) wires (48A, 48C, 48D), inner intermediate insulating layer 56, first metal sheet portion 66, and inner-insulating cover layer 72 in this sequence.

In the plurality of (four) wires 48, the first power source wire 48A, third power source wire 48C, and two lower signal wires 48D are arranged in parallel in spaced apart relation from each other in front-rear direction.

The inner intermediate insulating layer 56, first metal sheet portion 66, and inner-insulating cover layer 72 are formed into a sheet shape including the plurality of wires (48A, 48C, 48D) when projected in thickness direction, and are disposed at upper side of the plurality of wires 48.

On the upper portion of the first pedestals 81, a plurality of (four) bumps 83 corresponding to the plurality of wires 48 and a plurality of (three) gaps 84 formed between the plurality of bumps 83 are formed.

The bumps 83 and gaps 84 are formed so as to extend in width direction along the plurality of wires 48.

The first pedestals 81 do not include the metal supporting board 2. That is, the metal supporting board 2 is not disposed in the region forming the first pedestals 81 in plan view.

The second pedestals 82 are provided in the slider mounting region 90 and the piezoelectric element non-mounting region 92 (slider mounting region and piezoelectric element non-mounting region). To be specific, the second pedestals 82 are formed in a front end portion region of the inner-insulating cover layer 72 in spaced apart relation from each other in width direction.

The second pedestals 82 include the metal supporting board 2, insulating base layer 3, plurality of (four) wires (48A, 48C, 48D), intermediate insulating layer 5, second metal sheet portion 67, and insulating cover layer 7 in this sequence. To be more specific, the second pedestals 82 include the connection portion 26, inner-insulating base layer 36, plurality of (four) wires (48A, 48C, 48D), inner intermediate insulating layer 56, second metal sheet portion 67, and inner-insulating cover layer 72 in this sequence.

In the plurality of (four) wires 48, the first power source wire 48A, third power source wire 48C, and two lower signal wires 48D are arranged in parallel in spaced apart relation from each other in width direction.

The inner intermediate insulating layer 56, second metal sheet portion 67, and inner-insulating cover layer 72 have a sheet shape including the plurality of wires 48 when projected in thickness direction, and is disposed at the upper side of the plurality of wires 48.

On the upper portion of the second pedestals 82, a plurality of (four) bumps 83 corresponding to the plurality of wires 48 and a plurality of (three) gaps 84 formed between the plurality of bumps 83 are formed.

The bumps 83 and gaps 84 are formed so as to extend in front-rear direction along the plurality of wires 48.

A portion of the second pedestals 82 include the metal supporting board 2 disposed below the insulating cover layer 7. That is, the metal supporting board 2 is disposed at widthwise inner side in a region where the second pedestals 82 is formed in plan view, but the metal supporting board 2 is not disposed at widthwise outside.

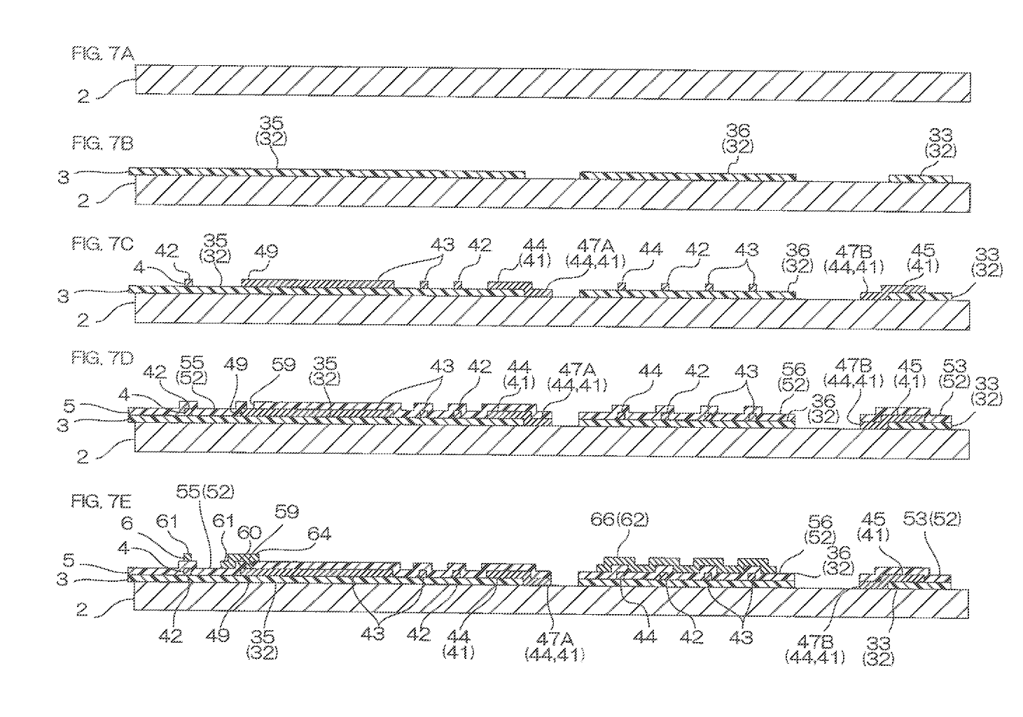

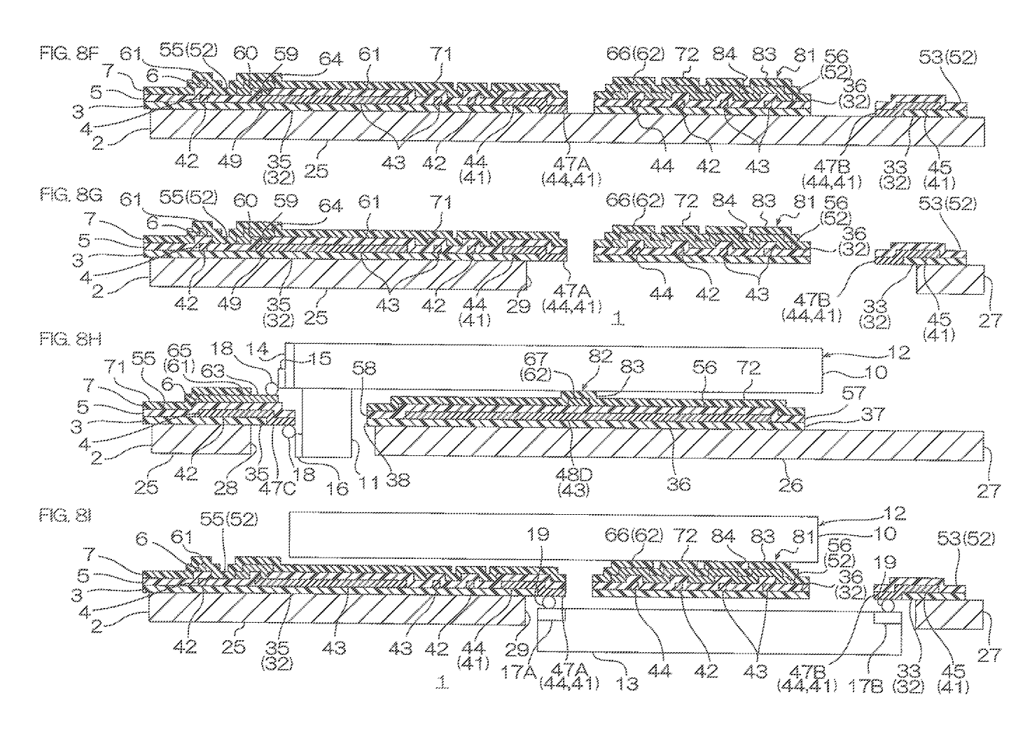

Next, description is given below of an embodiment of the method for producing a suspension board with circuits 1 with reference to FIG. 7A to FIG. 8I. FIG. 7A to FIG. 8G, and FIG. 8I show step diagrams in cross sections taken along A-A side shown in FIG. 1, and FIG. 8H shows step diagrams in cross sections taken along B-B side shown in FIG. 1.

In this method, as shown in FIG. 7A, first, the metal supporting board 2 is prepared.

Then, as shown in FIG. 7B, the insulating base layer 3 is formed on the metal supporting board 2.

To be specific, the insulating base layer 3 is formed on the upper face of the metal supporting board 2 as a pattern corresponding to the main body portion insulating base layer 31, and the gimbal portion insulating base layer 32 (rear insulating base layer 33, outer insulating base layer 34, front-insulating base layer 35, and inner-insulating base layer 36).

To form the insulating base layer 3 including the main body portion insulating base layer 31 and the gimbal portion insulating base layer 32, varnish of a photosensitive insulating material is applied on the metal supporting board 2 and then dried to form a base film.

Thereafter, the base film is exposed to light through a photomask, which is not shown. The photomask includes a pattern of shield portion and total light transmittance portion. The photomask is disposed on the base film so that the total light transmittance portion faces the portion where the insulating base layer 3 is formed, and the shield portion faces the portion where the insulating base layer 3 is formed, and the base film is exposed to light.

Thereafter, the base film is developed, and as necessary heated to allow thermosetting, thereby forming the insulating base layer 3 including the pattern of the main body portion insulating base layer 31 and the gimbal portion insulating base layer 32.

Then, as shown in FIG. 7C, the first conductive pattern 4 is formed on the insulating base layer 3.

To be specific, the first conductive pattern 4 is formed on the upper face of the insulating base layer 3 and the metal supporting board 2 by a pattern forming method of additive method or subtractive method, preferably by additive method.

In this manner, as shown in FIG. 1, the first conductive pattern 4 is formed so as to include the piezoelectric element connection circuit 41 (front piezoelectric element connection circuit 44, rear piezoelectric element connection circuit 45), light emitting element connection circuit 42, and first head connection circuit 43. The front piezoelectric element connection terminal 47A, rear piezoelectric element connection terminal 47B, and light emitting element connection terminal 47C are formed so as to drop on the upper face of the metal supporting board 2.

Then, as shown in FIG. 7D, the intermediate insulating layer 5 is formed on the first conductive pattern 4 and insulating base layer 3.

To be specific, the intermediate insulating layer 5 is formed on the upper face of the first conductive pattern 4 and insulating base layer 3 as a pattern corresponding to the main body portion intermediate insulating layer 51 and the gimbal portion intermediate insulating layer 52 (rear intermediate insulating layer 53, outer intermediate insulating layer 54, front intermediate insulating layer 55, and inner intermediate insulating layer 56).

At this time, the intermediate insulating layer 5 is formed so that a plurality of (four) through holes 59 are formed on the front intermediate insulating layer 55, and a plurality of (ten) terminal openings 50 are formed on the main body portion intermediate insulating layer 51. Meanwhile, the intermediate insulating layer 5 is formed so as to cover the upper face and side faces of the front piezoelectric element connection terminal 47A, rear piezoelectric element connection terminal 47B, and light emitting element connection terminal 47C.

The intermediate insulating layer 5 is formed in the same manner as in the method for forming the insulating base layer 3.

Then, as shown in FIG. 7E, the second conductive pattern 6 is formed on the intermediate insulating layer 5.

To be specific, the second conductive pattern 6 is formed on the upper face of the intermediate insulating layer 5 by a pattern forming method such as additive method or subtractive method, preferably, additive method.

In this manner, as shown in FIG. 2, the second conductive pattern 6 is formed so as to include the second head connection circuit 61 and metal sheet portion 62 (first metal sheet portion 66, second metal sheet portion 67).

At the same time with forming the second conductive pattern 6, the through hole 59 is filled with the same material as that of the second conductive pattern 6 to form the via conductive portion 60.

Then, as shown in FIG. 8F, the insulating cover layer 7 is formed on the second conductive pattern 6 and intermediate insulating layer 5.

To be specific, the insulating cover layer 7 is formed on the second conductive pattern 6 and intermediate insulating layer 5 as a pattern corresponding to the front-insulating cover layer 71 and inner insulating cover layer 72.

At this time, the insulating cover layer 7 is formed so that the upper face and side faces of the head connection terminals 63 are exposed.

Then, as shown in FIG. 8G, the metal supporting board 2 is trimmed so that the main body opening 27, front opening 28, and center opening 29 are formed by, for example, etching.

Then, as necessary, a plated layer is formed on the surface of the plurality of terminals. To be specific, a plated layer, which is not shown, is formed by plating such as electroless plating and electrolytic plating, preferably by, electrolytic plating.

In this manner, the suspension board with circuits 1 is completed.

As shown in FIG. 8H and FIG. 8I, the slider unit 12 and the plurality of (two) piezoelectric elements 13 are mounted on the suspension board with circuits 1.

As shown in FIG. 8H, the slider unit 12 includes the slider 10 and the light emitting device 11.

The slider 10 is formed into a generally rectangular box shape in plan view, and a magnetic head 14 is mounted on the slider 10. The magnetic head 14 is provided at the front cud portion of the slider 10, for reading and writing on a magnetic disk, which is not shown. A head-side terminal 15 is formed at the lower side portion of the front end portion of the magnetic head 14.

The light emitting device 11 is formed into a generally rectangular shape in plan view, having a smaller contour than that of the slider 10. The light emitting device 11 is provided at the lower face of the front side in front-rear direction of the slider 10. The light emitting device 11 is a heat-assisted device including, for example, laser diode, and can heat recording face of magnetic disk, which is not shown, by laser beam. The light emitting element-side terminal 16 is formed at the lower side portion of the front end portion of the light emitting element 11.

Upon mounting the slider unit 12, first, the slider unit 12 is disposed on the slider mounting region 90. To be specific, the slider unit 12 is disposed from above the suspension board with circuits 1 so that the light emitting element 11 is inserted in the front opening 28.

At this time, the slider 10 is mounted on the first pedestals 81 and the second pedestals 82. That is, the lower face of the slider 10 contacts the plurality of first pedestals 81 and the plurality of second pedestals 82, and the portion of the suspension board with circuits 1 other than the first pedestals 81 and the second pedestals 82 do not contact the slider 10.

An adhesive (not shown in the figure) is disposed between the first pedestals 81 and second pedestals 82, and the slider 10. In this manner, the slider unit 12 and the suspension hoard with circuits 1 are fixed.

Then, a first joint material 18 is disposed between the head-side terminal 15 and the head-connection terminals 63, and between the light emitting element-side terminal 16 and the light emitting element connection terminal 41, and thereafter heating such as reflowing is performed.

Examples of the first joint material 18 include conductive materials such as solder and conductive adhesive (for example, silver paste, etc.).

In this manner, the first joint material 18 melts and flows, and then solidified. As a result, the head-connection terminals 63 are electrically connected to the head-side terminal 15 of the magnetic head 14, and the light emitting element connection terminal 47C is electrically connected to the light emitting element-side terminal 16 of the light emitting element 11.

As shown in FIG. 8I, a pair of piezoelectric elements 13 are actuators capable of expansion and contraction in front-rear direction, and are formed into a generally rectangular shape in plan view extending in front-rear direction. Expansion and contraction of the piezoelectric element 13 allow for subtle adjustment of the positions of the gimbal portion 22, and the slider unit 12. The piezoelectric element-side front terminal 17A and the piezoelectric element-side rear terminal 17B are formed on the front end portion and the rear end portion of the upper face of the piezoelectric element 13, respectively.

Upon mounting the piezoelectric element 13, first, the piezoelectric element 13 is disposed on the piezoelectric clement mounting region 91. To be specific, the piezoelectric element 13 is disposed from below the suspension board with circuits 1 so as to be included in the center opening 29 when projected in thickness direction.

Then, a second joint material 19 is disposed between the piezoelectric element-side front terminal 17A and the front piezoelectric element connection terminal 47A, and between the piezoelectric element-side rear terminal 17B and the rear piezoelectric element connection terminal 47B, and thereafter, heating such as reflowing is performed.

For the second joint material 19, those conductive materials given as examples of the first joint material 18 are used.

In this manner, the second joint material 19 melts and flows, and then solidified. As a result, the piezoelectric element-side front terminal 17A and the front piezoelectric element connection terminal 47A are electrically connected, and the piezoelectric element-side rear terminal 17B and the rear piezoelectric element connection terminal 47B are electrically connected. The piezoelectric element 13 is fixed on the lower face of the suspension board with circuits 1 across the front piezoelectric element connection terminals 47A and the rear piezoelectric element connection terminals 47B.

The suspension board with circuits 1 on which the slider unit 12 and piezoelectric element 13 can be mounted includes first pedestals 81 that support the slider unit 12. The first pedestals 81 include the insulating base layer 3, first conductive pattern 4, intermediate insulating layer 5, second conductive pattern 6, and insulating cover layer 7. The first conductive pattern 4 includes a plurality of wires 48 (first power source wire 48A, third power source wire 48C, and lower signal wire 48D) in spaced apart relation from each other arranged in parallel.

Therefore, the first pedestals 81 can be provided on the region where the wires 48 are formed, and therefore the dedicated space for disposing the first pedestals 81 does not have to be provided. As a result, degree of freedom in disposing the first pedestals 81 and wires 48 improves.

On the first pedestals 81, the insulating cover layer 7 is disposed on the plurality of wires 48, and therefore the plurality of bumps 83 extending along the plurality of wires 48 are formed on the upper portion of the first pedestals 81. Therefore, the slider unit 12 is mounted on the plurality of long and narrow bumps 83, and therefore the slider unit 12 can be supported stably.

In the first pedestals 81 the insulating cover layer 7 is disposed on the plurality of wires 48, and therefore the gaps 84 along the plurality of wires 48 are formed on the upper portion of the first pedestals 81. Therefore, even if adhesive is excessively supplied on the first pedestals 81, the excessive adhesive can be discharged from the region of the first pedestals 81 along the gaps 84. That is, positioning failure of the slider unit 12 due to staying of the excessive adhesive can be suppressed. Thus, sufficient adhesive can be disposed on the first pedestals 81, and the slider unit 12 can be stably fixed to the first pedestals 81 reliably.

The first pedestals 81 are composed of the insulating base layer 3, first conductive pattern 4, intermediate insulating layer 5, second conductive pattern 6, and insulating cover layer 7, and therefore a layer for adjusting the height (for example, insulating layer) does not have to be formed separately just for forming the first pedestals 81. Thus, increase in the number of production processes of the suspension hoard with circuits 1 can be prevented. When the height adjustment layer is an insulating layer formed from, for example, varnish of a photosensitive insulating material, along with increase in the number of production processes, the number of heat treatment increases. However, with the suspension board with circuits 1, such increase in the number of heat treatment can be suppressed, and heat damages can be suppressed.

The suspension board with circuits 1 includes the first metal sheet portion 66 having a sheet shape extending in plane direction so that the second conductive pattern 6 includes at least two adjacent wires (to be specific, first power source wire 48A, third power source wire 48C, and lower signal wire 48D) of the plurality of wires 48 when projected in thickness direction.

Therefore, the first pedestals 81 have excellent rigidity, and even with the region (for example, piezoelectric element mounting region 91) not including the metal supporting board 2, the slider unit 12 can be reliably supported.

The piezoelectric element 13 can be mounted on the suspension board with circuits 1, and the first pedestals 81 and second pedestals 82 can be included. The first pedestals 81 are disposed in the region where the slider mounting region 90 and the piezoelectric element mounting region 91 overlap, and the metal supporting board 2 is not included below the insulating base layer 3. Meanwhile, the second pedestals 82 are disposed in the region where the slider mounting region 90 and the piezoelectric element non-mounting region 92 overlap, and the metal supporting board 2 is included below the insulating base layer 3.

Therefore, the first pedestals 81 can support the slider unit 12 in the piezoelectric element mounting region 91, and the piezoelectric element mounting region 91 can be effectively used. Meanwhile, the second pedestals 82 can support the slider unit 12 in the piezoelectric element non-mounting region 92 with the metal supporting hoard 2 even more reliably.

### Second Embodiment

With reference to FIG. 9 to FIG. 11, the suspension board with circuits 1 of the second embodiment is described. In the second embodiment, those members that are the same as those in the first embodiment are given the same reference numerals, and description thereof is omitted.

In the first embodiment shown in FIG. 1 to FIG. 8, the first conductive pattern 4 includes the plurality of wires 48, and the second conductive pattern 6 includes the first metal sheet portion 66. But for example, as shown in FIGS. 9 to 11, the first conductive pattern 4 can include the metal sheet portion and the second conductive pattern 6 can include the plurality of wires.

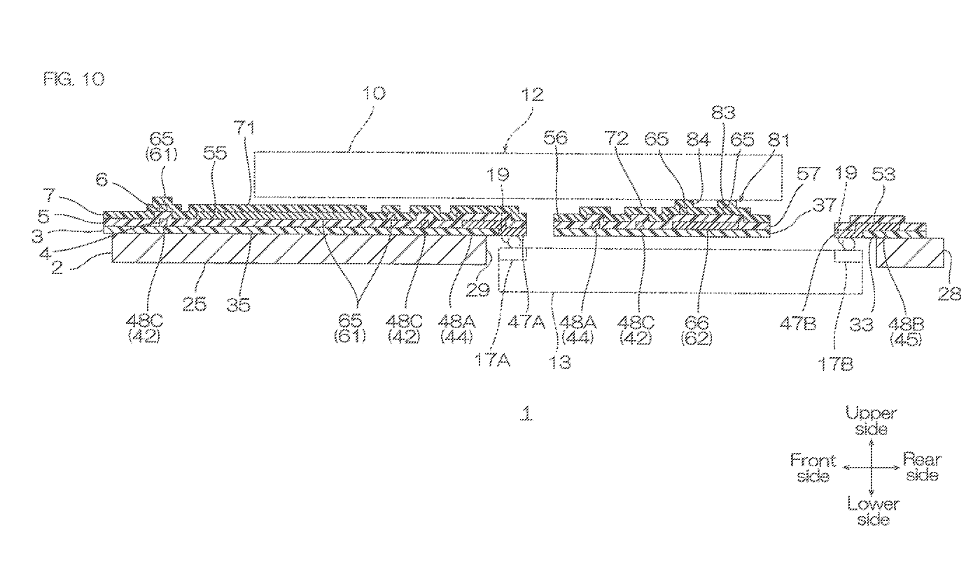

In the second embodiment, as shown in FIG. 10, the first pedestals 81 include the insulating base layer 3, first metal sheet portion 66, intermediate insulating layer 5, plurality of (two) wires 65, and insulating cover layer 7 in this sequence. To be more specific, the first pedestals 81 include the inner-insulating base layer 36, first metal sheet portion 66, inner intermediate insulating layer 56, plurality of (two) upper signal wires 65 arranged in parallel, and inner-insulating cover layer 72 in this sequence.

The first metal sheet portion 66 has a sheet shape including a plurality of (two) upper signal wires 65 when projected in thickness direction, and is disposed below the plurality of wires 48.

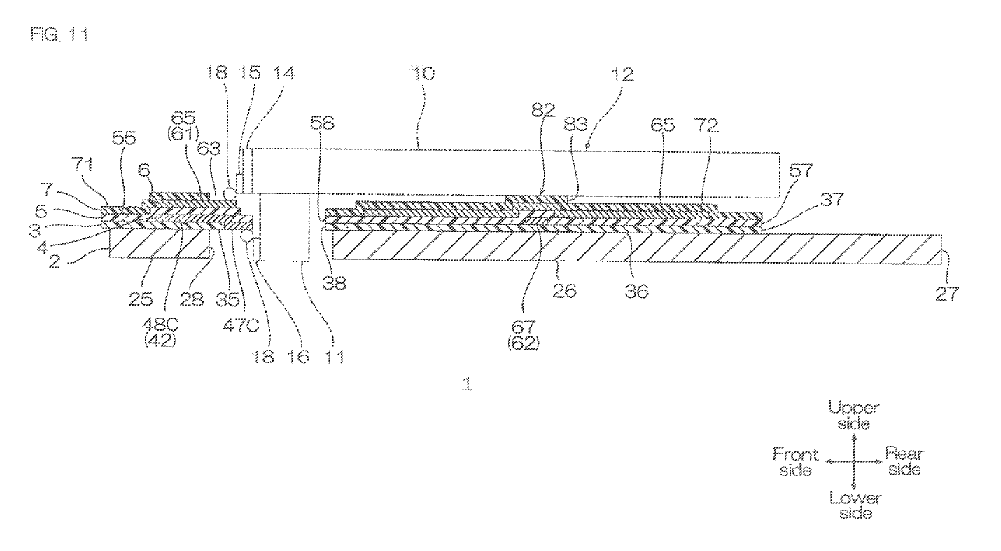

The second pedestals 82 include, similarly, as shown in FIG. 11, the insulating base layer 3, second metal sheet portion 67, intermediate insulating layer 5, plurality of (two) wires 65, and insulating cover layer 7 in this sequence. To be more specific, the second pedestals 82 include the connection portion 26, inner-insulating base layer 36, second metal sheet portion 67, inner intermediate insulating layer 56, plurality of (two) upper signal wires 65 arranged in parallel, and inner-insulating cover layer 72 in this sequence.

The second metal sheet portion 67 has a sheet shape including the plurality of (two) upper signal wires 65 when projected in thickness direction, and is disposed below the plurality of wires 48.

In the second embodiment, for example, as shown in FIG. 9, the lower connecting portions 49 and upper connecting portions 64 are formed on the outer insulating base layer 34 and outer intermediate insulating layer 54 corresponding to the outrigger portion 24. The lower signal wire 48D of the first head connection circuit 43 and the upper signal wires 65 of the second head connection circuit 61 are formed in correspondence with the position of the lower connecting portion 49 and upper connecting portions 64.

The second embodiment also has operations and effects as those in the first embodiment. That is, the first pedestals 81 have excellent rigidity, and even in the region not including the metal supporting board 2 (for example, piezoelectric element mounting region 91), the slider unit 12 can be supported reliably.

### OTHER MODIFIED EXAMPLES

In the first embodiment, the first pedestals 81 and second pedestals 82 include a plurality of (four) wires 48, but the number of the wires is not limited, and for example, 2, 3, or 5 or more wires can be included.

In the second embodiment, the first pedestals 81 and second pedestals 82 include a plurality of (two) wires, but the number of the wires is not limited, and for example, three or more wires can be included.

In the first embodiment and second embodiment, two first pedestals 81 and two second pedestals 82 are provided, but the number of the pedestals is not limited. For example, one first pedestal 81 only can be included, and one second pedestals 82 only can be included, and furthermore, three or more first pedestals 81 and second pedestals 82 can be included.

In the first embodiment and second embodiment, the shape of the metal sheet portion 62 (first metal sheet portion 66, second metal sheet portion 67) is a generally rectangular shape in plan view, but the shape is not limited, and can be an oval shape in plan view.

While the illustrative embodiments of the present invention are provided in the above description, such is for illustrative purpose only and it is not to be construed as limiting in any manner. Modification and variation of the present invention that will be obvious to those skilled in the art is to be covered by the following claims.

1. A suspension board with circuits, wherein a slider can be mounted thereon, the suspension board with circuits comprising:
a pedestal that supports the slider,
the pedestal comprises
a first insulating layer,
a first metal layer disposed on the first insulating layer,
a second insulating layer disposed on the first metal layer,
a second metal layer disposed on the second insulating layer, and
a third insulating layer disposed on the second metal layer, and
at least one of the first metal layer and the second metal layer comprises a plurality of wires arranged in parallel in spaced apart relation from each other.

2. The suspension board with circuits according to claim 1, wherein one of the first metal layer and the second metal layer includes the plurality of wires, and
the other of the first metal layer and the second metal layer has a sheet shape extending in a plane direction of the suspension board with circuits so as to include at least two adjacent wires of the plurality of wires when projected in thickness direction.

3. The suspension board with circuits according to claim 2, wherein the first metal layer includes the plurality of wires, and
the second metal layer has the sheet shape.

4. The suspension hoard with circuits according to claim 2, wherein the first metal layer has the sheet shape, and
the second metal layer has the plurality of wires.

5. The suspension board with circuits according to claim 1, wherein a piezoelectric element can be mounted on the suspension hoard with circuits,
the pedestal includes a first pedestal and a second pedestal,
the first pedestal is disposed in a region where a slider mounting region overlaps a piezoelectric element mounting region, and does not include a metal support layer below the first insulating layer, and
the second pedestal is disposed in the slider mounting region, and includes a metal support layer below the first insulating layer.
